(19) United States
(12) Patent Application Publication
(10) Pub. No.: US 2023/0253636 A1
(43) Pub. Date: Aug. 10, 2023

(54) DISCHARGE APPARATUS FOR DISCHARGING ENERGY, APPLIANCE APPARATUS HAVING AN ELECTRICAL APPLIANCE AND A DISCHARGE APPARATUS, METHOD FOR OPERATING AND METHOD FOR PRODUCING A DISCHARGE APPARATUS

(71) Applicant: ZF Friedrichshafen AG, Friedrichshafen (DE)

(72) Inventor: Thomas WOLF, Auerbach (DE)

(73) Assignee: ZF Friedrichshafen AG, Friedrichshafen (DE)

(21) Appl. No.: 18/166,959

(22) Filed: Feb. 9, 2023

(30) Foreign Application Priority Data
Feb. 10, 2022 (DE) 10 2022 201 378.6

(51) Int. Cl. H01M 10/44; H01C 1/08; H05K 1/18

(52) U.S. Cl. CPC H01M 10/44; H01C 1/08; H05K 1/18; H05K 7/20

(57) ABSTRACT

A discharge apparatus for discharging energy includes a control board, a carrier board, a connecting device, and a discharge resistor. The control board is designed to control an electrical appliance for a vehicle. The carrier board has an electrically conductive interface. The connecting device is electrically conductive and is formed so as to electrically connect the interface to the control board. The discharge resistor is arranged in or on the carrier board and is electrically connected to the interface. In addition, the discharge resistor is designed to discharge the energy when the interface is electrically connected to the control board.

### CROSS-REFERENCE TO RELATED APPLICATION

This application claims priority to German Application No. DE 10 2022 201 378.6, filed on Feb. 10, 2022, the entirety of which is hereby fully incorporated by reference herein.

### FIELD

The present approach relates to a discharge apparatus for discharging energy, an appliance apparatus having an electrical appliance and a discharge apparatus, a method for operating a discharge apparatus and a method for producing a discharge apparatus.

### BACKGROUND AND SUMMARY

In electrical appliances which are operated on a voltage of 48 volts or a high voltage, for example of more than 60 volts DC, it is necessary that the dedicated charged DC-link capacitance of the appliance and possibly also the external DC-link capacitances in the system are discharged.

Against this background, the present approach provides an improved discharge apparatus for discharging energy, an improved appliance apparatus having an electrical appliance and a discharge apparatus, a method for operating an improved discharge apparatus and a method for producing an improved discharge apparatus in accordance with the present disclosure. Advantageous configurations also result from the description below.

The advantages which can be achieved with the proposed approach consist in that, in the case of an energy discharge, an improved heat dissipation of the power losses can be ensured.

A discharge apparatus for discharging energy has a control board, a carrier board, a connecting device and a discharge resistor. The control board is designed to control an electrical appliance for a vehicle. The carrier board has an electrically conductive interface. The connecting device is electrically conductive and is formed so as to electrically connect the interface to the control board. The discharge resistor is arranged in or on the carrier board and is electrically connected or connectable to the interface. In addition, the discharge resistor is designed to discharge the energy when the interface is electrically connected to the control board.

The control board and the carrier board may be two different printed circuit boards. The discharge apparatus can be designed to discharge, as the energy, an energy charged in a DC-link capacitance from the control board via the carrier board. For example, the discharge resistor is designed to discharge the energy charged in the DC-link capacitance, which can be a dedicated charged DC-link capacitance of the appliance and/or an external DC-link capacitance in the system. During discharge, the discharge resistor can be designed to convert, as the energy, electrical energy at least partially into thermal energy/heat. The electrical appliance can be in the form of an electrical appliance which can be used in a vehicle and can be operated, for example, on an electrical voltage of 48 volts or a high voltage, for example of more than 60 volts. The connecting device can be in the form of a line, for example a flat ribbon cable, or in the form of a plug-type or press-fit contact. Thanks to the arrangement of the discharge resistor on the carrier board which is arranged externally with respect to the control board of the electrical appliance, the energy can be discharged from the control board advantageously on a dedicated component part remote from the control board.

The discharge apparatus can have a cooling device, which is designed to dissipate or cool heat from the discharge resistor. Thus, overheating of the carrier board can be counteracted.

In accordance with one embodiment, the cooling device can be in the form of a passive cooling device and/or an active cooling device. As a passive cooling device, the cooling device can have at least one heat sink, which can be arranged, for example, on a surface of the carrier board. As an active cooling device, the cooling device can actively cool, for example using water, a surface of the carrier board. A thermally conductive paste can be arranged between the carrier board and the cooling device.

For example, the carrier board can be in the form of an FR4 printed circuit board or an IMS printed circuit board. As FR4 printed circuit board, the printed circuit board can be particularly heat-resistant owing to poorly flammable and flame-retardant composite materials consisting of epoxy resin and/or fiberglass fabric. The abbreviation “FR” stands for “flame-retardant”. A copper layer thickness of the FR4 printed circuit board, which is in the form of a standard FR4 printed circuit board, can be up to 105 μm. Copper advantageously provides a very high coefficient of thermal conductivity. In accordance with one embodiment, the carrier board can also be in the form of an FR4 thick-copper printed circuit board having a copper layer thickness of, for example, more than 105 μm up to 400 μm, however. Such an FR4 thick-copper printed circuit board is suitable for high switching currents in the automobile electronics. As IMS (“Insulated Metal Substrate”) printed circuit board, the carrier board can have, for example, an aluminum substrate, a layer of insulation and a copper foil and can have overall a particularly high coefficient of thermal conductivity, for example higher than a standard FR4 printed circuit board. Alternatively, the carrier board can also be in the form of a so-called “Direct Copper Bond”, “DCB” for short. As a DCB, a particularly high degree of heat dissipation is enabled for the carrier board.

The discharge resistor can be in the form of a conductor track structure in or on the carrier board and/or in the form of at least one SMD component part in or on the carrier board. Such a conductor track structure enables advantageous spreading of the heat. The conductor track structure can have a rectangularly curved or convoluted profile.

It is furthermore advantageous if, in accordance with one embodiment, the discharge apparatus has a control component part arranged in or on the carrier board and/or the control board for controlling a switch for controlling the discharge resistor. The control component part can have the switch and can be in the form of, for example, a high-voltage MOSFET. Such a control component part can serve the purpose of activating a discharge process for the energy which can be performed by means of the discharge resistor. For example, the switch can be closed using the control component part in order to produce a mechanical and/or electrical connection between the interface and the discharge resistor in order to activate the discharge process and/or the switch can be opened in order to release the mechanical and/or electrical connection between the interface and the discharge resistor in order to deactivate the discharge process.

In addition, the discharge apparatus can have a control monitoring device, which is electrically connected to the discharge resistor and is arranged in or on the carrier board and/or the control board, wherein the control monitoring device is designed to monitor control of the discharge resistor. For the monitoring, the control monitoring device can be designed, for example, to perform an evaluation of the resistor network.

For example, the discharge apparatus can have a temperature sensor, which is arranged in or on the carrier board and/or the control board and is designed to sense a temperature, and/or a current sensor, which is arranged in or on the carrier board and/or the control board and is designed to sense a current intensity. The temperature sensor and/or current sensor can be connected to the control monitoring device in terms of signal technology. The temperature sensor can be in the form of a so-called “Negative Temperature Coefficient Thermistor”, “NTC” for short, for example, and/or can be designed to provide the sensed temperature for the control monitoring device. The current sensor can be in the form of a so-called “Shunt”, for example, and/or can be designed to provide the sensed current intensity for the control monitoring device. Thus, for example, an overcurrent measurement can take place. Such a temperature sensor and/or current sensor enables an evaluation of the resistor network in order to be able to perform, correspondingly, control of the discharge resistor. For example, the control monitoring device can be designed to control the switch for controlling the discharge resistor depending on the sensed current intensity and/or the sensed temperature. In accordance with one embodiment, the switch is closed when a defined maximum current intensity and/or maximum temperature has been reached in order to discharge the energy.

In addition or as an alternative, it is also possible for one or more other sensors to be used in addition to or instead of the temperature or current sensor, for example a voltage sensor.

An appliance apparatus has an electrical appliance and a discharge apparatus in one of the above-described variants. The appliance can be in the form of a drive device for moving a vehicle or an inverter for a vehicle.

A method for operating a discharge apparatus in one of the above-described variants has a control step, in which the discharge resistor is controlled so as to effect discharge of the energy using the discharge resistor. In the control step, a switch can be controlled so as to effect the discharge of the energy charged in the DC-link capacitance, for example by virtue of the energy being converted into heat.

This method can be implemented, for example, using software or hardware or using a combination of software and hardware, for example, in a control device.

A method for producing a discharge apparatus in one of the above-described variants has a provision step, an arrangement step and an electrical connection step. In the provision step, a carrier board is provided with an electrically conductive interface. In the arrangement step, the discharge resistor is arranged in or on the carrier board, wherein, in the arrangement step the discharge resistor is arranged in such a way that the discharge resistor is electrically connected to the interface. In the electrical connection step, the interface is electrically connected to the control board in order to produce the discharge apparatus.

This method can be implemented, for example, using software or hardware or using a combination of software and hardware, for example, in a control device.

The approach proposed here further provides an apparatus which is designed to perform, control or implement the steps of one variant of a method proposed here in corresponding devices. By means of this variant embodiment of the approach in the form of an apparatus it is also possible to achieve the object on which the approach is based quickly and efficiently.

An apparatus may be an electrical appliance which processes electrical signals, for example sensor signals, and outputs control signals on the basis thereof. The apparatus can have one or more suitable interfaces, which can be in the form of hardware and/or software. In the case of a hardware design, the interfaces can be, for example, part of an integrated circuit, in which functions of the apparatus are implemented. The interfaces can also be dedicated integrated circuits or at least partially consist of discrete components. In the case of a software design, the interfaces can be software modules, which are provided, for example, on a microcontroller in addition to other software modules.

Also advantageous is a computer program product with program code which can be stored on a machine-readable carrier such as a semiconductor memory, a hard disk drive or an optical memory and is used for performing the method according to one of the above-described embodiments when the program is run on a computer or an apparatus.

Exemplary embodiments of the approach proposed here are illustrated in the drawings and explained in more detail in the description below.

### BRIEF DESCRIPTION OF THE DRAWINGS

FIG. 1 shows a schematic illustration of a vehicle having a discharge apparatus in accordance with one exemplary embodiment for discharging energy;

FIG. 2 shows a schematic illustration of a discharge apparatus in accordance with one exemplary embodiment;

FIG. 3 shows a schematic illustration of a discharge apparatus in accordance with one exemplary embodiment;

FIG. 4 shows a flow chart of a method in accordance with one exemplary embodiment for operating a discharge apparatus; and

FIG. 5 shows a flow chart of a method in accordance with one exemplary embodiment for producing a discharge apparatus.

### DETAILED DESCRIPTION

In the description below of preferred exemplary embodiments of the present approach, identical or similar reference symbols are used for the similarly acting elements illustrated in the various figures, wherein no repeated description of these elements is provided.

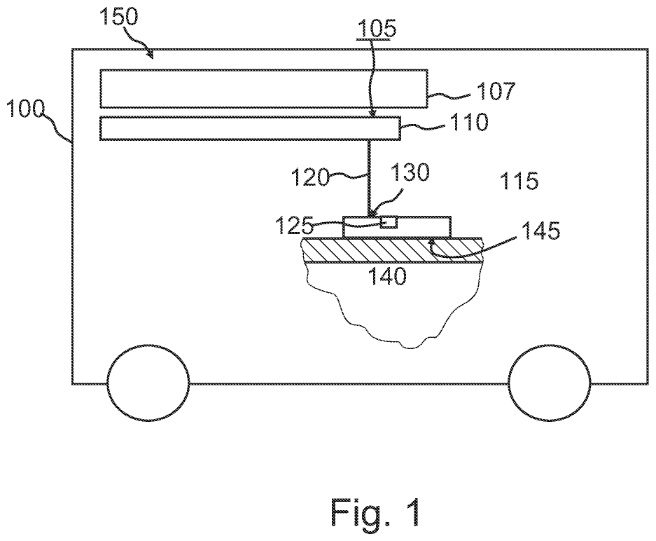

FIG. 1 shows a schematic illustration of a vehicle 100 having a discharge apparatus 105 in accordance with one exemplary embodiment for discharging energy. The discharge apparatus 105 is shown as a cross-sectional illustration from the side.

The discharge apparatus 105 is designed, in accordance with this exemplary embodiment, to discharge electrical energy, for example an energy charged in a DC-link capacitance of an electrical appliance 107. The electrical appliance 107 and the discharge apparatus 105 are, in accordance with this exemplary embodiment, accommodated in or on the vehicle 100 merely by way of example. The electrical appliance 107 can be operated on a voltage of 48 volts or a high voltage, for example of more than 60 volts DC. Merely by way of example, in accordance with this exemplary embodiment the electrical appliance 107 is a drive device for moving the vehicle 100, for example an electric motor and/or hybrid gear, or an inverter for the vehicle 100. In accordance with one alternative exemplary embodiment, the electrical appliance 107 is in the form of any other desired electrical appliance which can be used in a vehicle 100.

The discharge apparatus 105 has a control board 110, a carrier board 115, a connecting device 120 and a discharge resistor 125. The control board 110 is designed to control the electrical appliance 107 of the vehicle 100. The carrier board 115 has an electrically conductive interface 130. The connecting device 120 is electrically conductive and is formed so as to electrically connect the interface 130 to the control board 110. The discharge resistor 125 is arranged in or on the carrier board 115 and is electrically connected or connectable to the interface 130. In addition, the discharge resistor 125 is designed to discharge the energy when the interface 130 is electrically connected to the control board 110.

The connecting device 120 is, in accordance with this exemplary embodiment, in the form of a line, for example a flat ribbon cable, or in the form of a plug-type or press-fit contact. The interface 130 and the control board 110 are electrically connected to one another in accordance with this exemplary embodiment via the connecting device 120. The discharge resistor 125 is designed in accordance with this exemplary embodiment to convert, as the energy, electrical energy at least partially into thermal energy/heat.

In addition, the discharge apparatus 105 has, in accordance with this exemplary embodiment, a cooling device 140, which is designed to dissipate or cool heat from the discharge resistor 125. In accordance with this exemplary embodiment, the cooling device 140 is in the form of a passive cooling device and/or an active cooling device. As a passive cooling device, the cooling device 140 has at least one heat sink, which is arranged, for example, on a surface 145 of the carrier board 115. The surface 145, in accordance with this exemplary embodiment, is arranged remote from the carrier board 115. As an active cooling device, the cooling device 140, in accordance with one exemplary embodiment, is designed to actively cool the surface 145 of the carrier board 115, for example using water. In accordance with one exemplary embodiment, a thermally conductive paste is arranged between the carrier board 115 and the cooling device 140.

In accordance with this exemplary embodiment, the carrier board 115 is in the form of an FR4 printed circuit board or an IMS printed circuit board. A copper layer thickness of the FR4 printed circuit board in the form of a standard FR4 printed circuit board in accordance with one exemplary embodiment is up to 105 μm. In accordance with an alternative exemplary embodiment, the carrier board 115 is in the form of an FR4 thick-copper printed circuit board having a copper layer thickness of, for example, more than 105 μm up to 400 μm. As an IMS printed circuit board, the carrier board 115 in accordance with an alternative exemplary embodiment has an aluminum substrate, a layer of insulation and a copper foil. In accordance with a further alternative exemplary embodiment, the carrier board 115 is in the form of a “Direct Copper Bond”.

Together with the electrical appliance 107, the discharge apparatus 105 proposed here can also be referred to as an appliance apparatus 150.

In high-voltage projects with a voltage of greater than 60 volts DC, it is necessary that the dedicated charged DC-link capacitance of the appliance 107 and possibly also the external DC-link capacitances in the system are actively discharged within a specific time period. With the discharge apparatus 105 proposed here there is a possibility of converting the energy charged in the capacitance into heat via the discharge resistor 125. The thereby resultant heat should be cooled correspondingly in order to be able to maintain the discharge cycles and the discharge times, and therefore the discharge apparatus 105 also has the cooling device 140. With this discharge apparatus 105, an improved heat dissipation of the power losses can be ensured, and the production of the discharge circuit can take place by means of standard printed circuit board manufacture/population. Even in 48 V projects it may be that the energy stored in the DC link can result in a hazard and should therefore be discharged. In addition, it may be necessary in both systems, i.e. 48 V or high voltage, that an energy arising, for example, as a result of an overvoltage, needs to be dissipated within a time period.

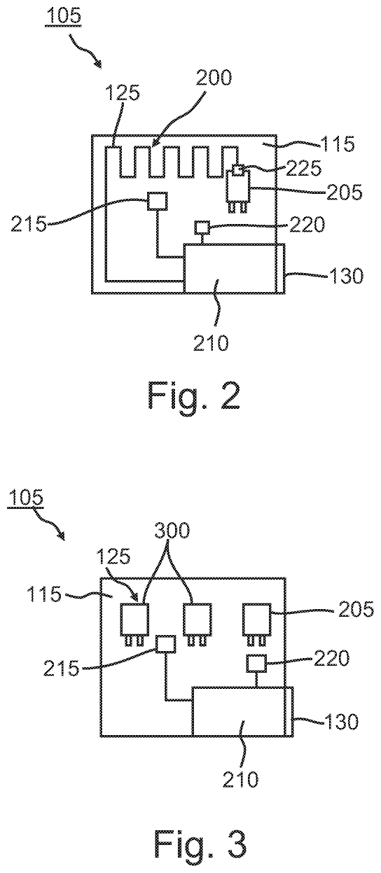

The discharge apparatus 105 proposed here advantageously enables active discharge via the discharge resistor 125 integrated in or on the carrier board 115. The actual discharge resistor 125 of the DC-link capacitance is in this case advantageously embodied as a component part/module which, in accordance with one exemplary embodiment, is mounted discretely on the carrier board 115, for example as an SMD component part, see FIG. 3. In accordance with another exemplary embodiment, the discharge resistor 125 is arranged as a conductor track structure on the surface 145 or a carrier board surface arranged opposite the surface 145, see FIG. 2. In accordance with further other exemplary embodiments, the discharge resistor 125 is integrated in the carrier board 115 as a conductor track structure or in the carrier board 115 as a discrete component part.

In accordance with different exemplary embodiments, an IMS (Insulated Metal Substrate) board or a standard FR4 printed circuit board or an FR4 thick-copper printed circuit board or a DCB (Direct Copper Bond) is used as carrier board 115.

DC isolation of the discharge circuit (high voltage) from the heat sink of the cooling device 140 takes place in accordance with one exemplary embodiment via the carrier board 115, for example with an FR4 core or as an IMS substrate. A thermal link of the carrier board 115 to the heat sink/cooling device 140 takes place, for example, via a thermally conductive paste, also referred to as “Thermal Interface Material”, or else directly.

The heat sink or the cooling takes place in accordance with different exemplary embodiments discretely/passively or actively, for example using water. A connection to the control board 110 takes place in accordance with one exemplary embodiment via the electrical connecting device 120, which is embodied, for example, via a flat ribbon cable line, plug-type or press contacts or the like. Circuit parts shown in FIGS. 2 and 3 for control, protection and diagnosis are, in accordance with different exemplary embodiments, integrated either on the control board 110 or on the carrier board 115 or both on the control board 110 and on the discharge resistor carrier board 115. This enables increasing flexibility. In addition, interface signals can be reduced between the two boards 110, 115 and/or can be built up as an independent component part/module that can be used over the entire discharge apparatus 105.

The discharge apparatus 105 proposed here can be used for any desired 48 V appliances 107, for example a plug-in hybrid gear for a mild hybrid vehicle 100 or for high-voltage inverters.

Otherwise, in the case of an alternatively possible active discharge via, for example, the electric machine of the vehicle 100, when using the discharge apparatus 105 proposed here no undesired rotary movements of the electric machine take place, with the result that, thanks to the discharge apparatus 105, advantageously a safer state of the electric drive system can be maintained. Otherwise, in the case of an alternatively possible active discharge via, for example, a DC-DC converter, wherein a discharge energy of the DC-link capacitance would only be recharged, for example from a high voltage to 12 V, thanks to the discharge apparatus 105 no inverter-external component is required for the discharge of the DC-link capacitance.

FIG. 2 shows a schematic illustration of a discharge apparatus 105 in accordance with one exemplary embodiment. This may be the discharge apparatus 105 described in FIG. 1. The control board of the discharge apparatus 105 is not illustrated in FIG. 2 merely for reasons of clarity.

In accordance with this exemplary embodiment, the discharge resistor 125 is in the form of a conductor track structure 200 in or on the carrier board 115. The conductor track structure 200 in accordance with this exemplary embodiment has a rectangularly curved or convoluted profile. In accordance with this exemplary embodiment, the conductor track structure 200 runs a course with nine turns.

In addition, the discharge apparatus 105 in accordance with this exemplary embodiment has a control component part 205, a control monitoring device 210, a temperature sensor 215 and/or a current sensor 220.

The control component part 205, in accordance with this exemplary embodiment, is arranged in or on the carrier board 110 or, in accordance with an alternative exemplary embodiment, in or on the control board and is designed to control a switch 225 for controlling the discharge resistor 125. The control component part 205, in accordance with this exemplary embodiment, has the switch 225 and is in the form of a high-voltage MOSFET, for example. The control component part, in accordance with this exemplary embodiment, is designed to activate a discharge process of the energy which can be performed by means of the discharge resistor 125. For example, in accordance with one exemplary embodiment, the switch 225 is closed using the control component part 205 in order to produce a mechanical connection between the interface 130 and the discharge resistor 125 in order to activate the discharge process and/or the switch 225 is opened in order to release the mechanical connection between the interface 130 and the discharge resistor 125 in order to deactivate the discharge process.

The control monitoring device 210 is electrically connected to the discharge resistor 125 and is arranged, in accordance with this exemplary embodiment, in or on the carrier board 115 and/or, in accordance with an alternative exemplary embodiment, in or on the control board. The control monitoring device 210 is designed to monitor control of the discharge resistor 125. For the monitoring, the control monitoring device 210 is designed, for example, to perform an evaluation of the resistor network.

For this purpose, the discharge apparatus 105 has the temperature sensor 215, which is arranged, in accordance with this exemplary embodiment, in or on the carrier board 115 or, in accordance with an alternative exemplary embodiment, in or on the control board and which is designed to sense a temperature. The current sensor 220 is arranged, in accordance with this exemplary embodiment, in or on the carrier board 115 or, in accordance with an alternative exemplary embodiment, in or on the control board and is designed to sense a current intensity. The temperature sensor 215 and/or current sensor 220 are connected in terms of signal technology to the control monitoring device 210 in accordance with this exemplary embodiment. The temperature sensor 215, in accordance with this exemplary embodiment, is in the form of a so-called “Negative Temperature Coefficient Thermistor”, “NTC” for short, for example, and/or is designed to provide the sensed temperature for the control monitoring device 210. The current sensor 220, in accordance with this exemplary embodiment, is in the form of a so-called “Shunt”, for example, and/or is designed to provide the sensed current intensity for the control monitoring device 210. Thus, for example, an overcurrent measurement and/or an overtemperature measurement take(s) place. In accordance with one exemplary embodiment, an evaluation of the resistor network takes place using the temperature sensor 215, current sensor 220 and/or the control monitoring device 210 in order to, for example, perform control of the discharge resistor 125 in a corresponding manner. For example, the control monitoring device 210 in accordance with one exemplary embodiment is designed to control the switch 225 for controlling the discharge resistor depending on the sensed current intensity and/or the sensed temperature. In accordance with one exemplary embodiment, the switch 225 is closed when a defined maximum current intensity and/or maximum temperature has/have been reached.

By way of summary, FIG. 2 also shows:
the control component part 205 in the form of circuit parts for the control, for example via a high-voltage MOSFET;
a circuit part protection, which performs, for example, an overcurrent measurement via current sensor 220 and/or an overtemperature measurement via temperature sensor 215; and
the control monitoring device 210 in the form of a circuit part diagnosis, which performs, for example, a current sensor measurement and evaluation of the resistor network.

By way of summary, the discharge apparatus 105 realizes improved heat dissipation as a standard resistance component part by virtue of spreading the heat through a resistance structure, in this case in the form of the conductor track structure 200, on or in the carrier board 110. In addition, in the case of the discharge apparatus 105 in accordance with this exemplary embodiment, integration of the control, protection and diagnosis takes place on the component part/module, in this case on the carrier board 110, or alternatively on the control board. The discharge apparatus 105 can be used across the project as a dedicated, qualified “component part/module”.

FIG. 3 shows a schematic illustration of a discharge apparatus 105 in accordance with one exemplary embodiment. This may be the discharge apparatus 105 described in FIG. 2, with the difference that the discharge resistor 125 in accordance with this exemplary embodiment is in the form of at least one SMD component part 300. The control board of the discharge apparatus 105 is not illustrated in FIG. 3 merely for reasons of clarity.

The SMD component part 300 is arranged, in accordance with this exemplary embodiment, in or on the carrier board 110. In accordance with this exemplary embodiment, the discharge resistor 125 comprises at least two of the SMD component parts 300, which are arranged adjacent to one another, for example, here.

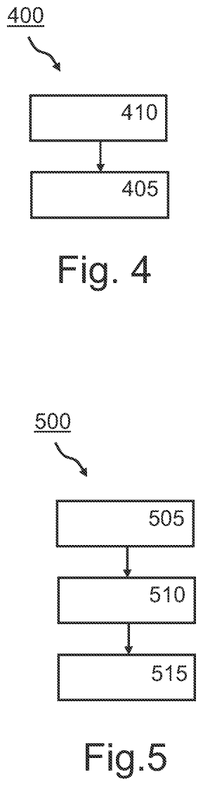

FIG. 4 shows a flow chart of a method 400 in accordance with one exemplary embodiment for operating a discharge apparatus. This may be the discharge apparatuses described in one of FIGS. 1 to 3.

The method 400 has a control step 405, in which the discharge resistor is controlled so as to effect discharge of the energy using the discharge resistor. In the control step 405, in accordance with one exemplary embodiment, a switch is controlled so as to effect the discharge of the energy charged in the DC-link capacitance, for example by virtue of the energy being converted into heat. The method 400 also has, in accordance with one exemplary embodiment, a provision step 410, in which the discharge apparatus is provided, prior to the control step 405.

FIG. 5 shows a flow chart of a method 500 in accordance with one exemplary embodiment for producing a discharge apparatus. This may be the discharge apparatuses described in one of FIGS. 1 to 3.

The method 500 has a provision step 505, an arrangement step 510 and an electrical connection step 515. In the provision step 505, a carrier board is provided with an electrically conductive interface. In the arrangement step 510, the discharge resistor is arranged in or on the carrier board, wherein, in the arrangement step 510, the discharge resistor is arranged in such a way that the discharge resistor is electrically connected to the interface. In the electrical connection step 515, the interface is electrically connected to the control board in order to produce the discharge apparatus.

The exemplary embodiments described and shown in the figures are only selected by way of example. Different exemplary embodiments can be combined with one another completely or in respect of individual features. It is also possible for one exemplary embodiment to be supplemented by features of a further exemplary embodiment.

In addition, the method steps proposed here can be implemented repeatedly and in a different sequence than that described.

If an exemplary embodiment includes an “and/or” conjunction between a first feature and a second feature, this should be understood to mean that the exemplary embodiment, in accordance with one embodiment, has both the first feature and the second feature and, in accordance with a further embodiment, has only the first feature or only the second feature.

### REFERENCE SYMBOLS

100 vehicle
105 discharge apparatus
107 electrical appliance
110 control board
115 carrier board
120 connecting device
125 discharge resistor
130 interface
140 cooling device
145 surface
150 appliance apparatus
200 conductor track structure
205 control component part
210 control monitoring device
215 temperature sensor
220 current sensor
225 switch
300 SMD component part
400 method for operating a discharge apparatus
405 control step
410 provision step
500 method for producing a discharge apparatus
505 provision step
510 arrangement step
515 connection step

1. A discharge apparatus for discharging energy comprising:
a control board configured to control an electrical appliance for a vehicle;
a carrier board having an electrically conductive interface;
an electrically conductive connecting device configured to electrically connect the electrically conductive interface to the control board; and
a discharge resistor arranged in or on the carrier board and that is configured to be electrically connected to the electrically conductive interface and to discharge the energy when the interface is electrically connected to the control board.

2. The discharge apparatus according to claim 1, further comprising:
a cooling device configured to dissipate or cool heat from the discharge resistor.

3. The discharge apparatus according to claim 2, wherein the cooling device comprises a passive cooling device and/or an active cooling device.

4. The discharge apparatus according to claim 1, wherein the carrier board comprises an FR4 printed circuit board or an IMS printed circuit board.

5. The discharge apparatus according to claim 1, wherein the discharge resistor comprises:
a conductor track structure in or on the carrier board; and/or
at least one SMD component part in or on the carrier board.

6. The discharge apparatus according to claim 1, further comprising a control component part arranged in or on the carrier board.

7. The discharge apparatus according to claim 1, further comprising the control board for controlling a switch for controlling the discharge resistor.

8. The discharge apparatus according to claim 1, further comprising:
a control monitoring device electrically connected to the discharge resistor and arranged in or on the carrier board and/or the control board, wherein the control monitoring device is configured to monitor control of the discharge resistor.

9. The discharge apparatus according to claim 1, further comprising:
a temperature sensor arranged in or on the carrier board and/or the control board, wherein the temperature sensor is configured to sense a temperature.

10. The discharge apparatus according to claim 1, further comprising:
a current sensor arranged in or on the carrier board and/or the control board, wherein the current sensor is configured to sense a current intensity.

11. An appliance apparatus comprising:
an electrical appliance; and
the discharge apparatus according to claim 1,
wherein the electrical appliance comprises a drive device for moving a vehicle or an inverter for a vehicle.

12. A method of operating a discharge apparatus, wherein the discharge apparatus includes a carrier board having an electrically conductive interface, an electrically conductive connecting device configured to electrically connect the electrically conductive interface to the control board, and a discharge resistor arranged in or on the carrier board and electrically connected to the electrically conductive interface,
wherein the method comprises:
controlling, by a control board, the discharge resistor to discharge energy using the discharge resistor.

13. The method according to claim 12, further comprising:
dissipating heat from the discharge resistor by a cooling device.

14. The method according to claim 12, further comprising:
controlling, by the control board, a switch to control the discharge resistor.

15. The method according to claim 12, further comprising:
monitoring the control of the discharge resistor by a control monitoring device electrically connected to the discharge resistor and arranged in or on the carrier board and/or the control board.

16. The method according to claim 12, further comprising:
sensing a temperature with a temperature sensor arranged in or on the carrier board and/or the control board.

17. The method according to claim 12, further comprising:
Sensing a current intensity with a current sensor arranged in or on the carrier board and/or the control board.

18. A method for producing a discharge apparatus comprising:
providing a carrier board with an electrically conductive interface;
arranging the discharge resistor in or on the carrier board such that the discharge resistor is electrically connected to the electrically conductive interface; and
electrically connecting the electrically conductive interface to a control board configured to control an electrical appliance for a vehicle.

19. The method according to claim 18, further comprising:
providing a cooling device configured to dissipate or cool heat from the discharge resistor.

20. The method according to claim 18, further comprising:
providing a control component part arranged in or on the carrier board.
